(19) United States
(12) Patent Application Publication
(10) Pub. No.: US 2014/0116493 A1
(43) Pub. Date: May 1, 2014

(54) SOLAR CELL MODULE AND METHOD FOR MANUFACTURING SAME

(71) Applicants: Kwanghee Lee, Gwangju (KR); Jongjin Lee, Gwangju (KR); Hyungcheol Back, Gwangju (KR)

(72) Inventors: Kwanghee Lee, Gwangju (KR); Jongjin Lee, Gwangju (KR); Hyungcheol Back, Gwangju (KR)

(73) Assignee: Gwangju Institute of Science and Technology, Buk-gu, Gwangju (KR)

(21) Appl. No.: 14/130,265

(22) PCT Filed: Dec. 12, 2011
(86) PCT No.: PCT/KR2011/009555

§ 371 Date: Dec. 30, 2013

(30) Foreign Application Priority Data
Jul. 22, 2011 (KR) 10-2011-0072863

(51) Int. Cl. H01L 31/05

(52) U.S. Cl. CPC H01L 31/0504
USPC 136/244; 438/80

(57) ABSTRACT

Disclosed herein are a solar cell module and a manufacturing method thereof. In the solar cell module according to the present invention, disposition structure of charge transport layers of individual cells configuring the solar cell is different, but the charge transport layers are disposed so as to be alternated with neighboring cells and the individual cells are connected in series to each other using an electrode as a connecting part between cells, such that a current may be decreased and a voltage may be increased, and an additional space for connecting the individual cells in series to each other is not required, such that high photovoltaic conversion efficiency and low power loss may be obtained at the same time.

### TECHNICAL FIELD

The present invention relates to a solar cell module and a manufacturing method thereof, and more specifically, to a solar cell module having improved structure and performance by disposing charge transport layers of individual cells configuring the solar cell module so as to be alternated with neighboring cells and using an electrode as a connecting part between the cells, and a manufacturing method thereof.

### BACKGROUND ART

In general, a solar cell used in solar power generation is manufactured in a module shape in which a plurality of solar cells are disposed in a package depending on required properties of a cell capacitance, and the like.

FIG. 1 is a schematic view showing a solar cell module according to the related art.

Referring to FIG. 1, the solar cell module includes an upper substrate 10 and a lower substrate 30, a plurality of solar cells 20a, 20b and 20c connected in series or in parallel to each other by a metal ribbon 23 between the upper substrate 10 and the lower substrate 30, and a filler 27 filling a space between the upper substrate 10 and the lower substrate 30.

The above-described module is formed by using a scheme in which individual solar cells are manufactured and then each cell is connected in series or parallel or a scheme in which each cell is configured by patterning cells manufactured in a large area and then each cell is connected in series or parallel.

Here, the serial connection between the solar cells has been used as a connecting scheme for minimizing a voltage decrease generated in a thin film conducting wire having low conductivity.

However, the current solar cell module separately requires a wiring area for the serial connection between individual cells, thereby causing a problem in that photovoltaic conversion efficiency of the entire module is deteriorated. In addition, the solar cell module has a problem in that power loss is increased due to resistance loss (I2R) caused by increasing a current of the entire module and decreasing a voltage thereof, in the case of an increasing area of individual cells and decreasing the number of connections in order to minimize the required wiring area as described above.

Meanwhile, a plurality of solar cells configuring a solar cell module are large classified into an inorganic solar cell, a dye-sensitized solar cell, and an organic solar cell depending on a material of a photoactive layer configuring each solar cell.

Among them, the photoactive layer of the organic solar cell has a bulk hetero junction structure of an electron donor: D and an electron acceptor: A. When light is irradiated on the organic solar cell, the light is absorbed to form an electron-hole pair in an excitation state in the photoactive layer, that is, an exciton, wherein the excitons are diffused in an arbitrary direction and separated into an electron and a hole when contacting a D-A interface. In addition, a charge transport layer, that is, an electron transport layer (ETL) and a hole transport layer (HTL) are positioned in upper and lower parts of the photoactive layer, wherein the ETL captures separated electrons to deliver the electrons to a cathode, and the HTL captures separated holes deliver the holes to an anode. As described above, charges collected in the anode and the cathode form a photocurrent.

Therefore, the electron and the hole generated in the photoactive layer have a property in which a transport direction is determined depending on a disposition structure of the charge transport layers positioned at upper and lower parts of the photoactive layer, such that a direction of the photocurrent or a pole of an open voltage may be changed.

### DETAILED DESCRIPTION OF THE INVENTION

### Technical Problem

An object of the present invention is to provide a solar cell module capable of having improved structure and performance by disposing charge transport layers of individual cells configuring the solar cell module so as to be alternated with neighboring cells, forming a photoactive layer integrally so as to penetrate through each cell, and using an electrode as a connecting part between the cells.

In addition, another object of the present invention is to provide a manufacturing method of a solar cell module capable of manufacturing individual cells configuring the solar cell module at one time.

### Technical Solution

According to an exemplary embodiment of the present invention, there is provided a solar cell module including: a plurality of first solar cells including a first electrode, a photoactive layer, and a second electrode; and a plurality of second solar cells including a first electrode, a photoactive layer, and a second electrode, wherein the first solar cell and the second solar cell include at least one charge transport layer selected from a hole transport layer and an electron transport layer, the charge transport layers between the first solar cell and the second solar cell that are alternated with each other so as to neighbor and be adjacent to each other being disposed so as to be alternated with each other; the first solar cell and the second solar cell are connected to neighboring cells through the first electrode or the second electrode, and photoactive layers of the first solar cell and the second solar cell are formed integrally so as to penetrate through each cell.

According to another exemplary embodiment of the present invention, there is provided a manufacturing method of a solar cell module, the manufacturing method including: forming a first electrode part on a substrate, the first electrode part including a plurality of first electrodes spaced apart from each other; forming a first charge transport part by disposing first hole transport layer and first electron transport layer on the first electrode part so as to be alternated with each other; forming a photoactive layer integrally on the first charge transport part; forming a second charge transport part by disposing second electron transport layer and second hole transport layer on the photoactive layer so as to be alternated with each other; and forming a second electrode part on the second charge transport part, the second electrode part including a plurality of second electrodes spaced apart from each other.

### Advantageous Effects

With the solar cell module according to the present invention, the individual cells configuring the module are connected in series to each other, such that a current may be decreased and a voltage may be increased, and additional space for connecting the individual cells in series to each other is not required, such that high photovoltaic conversion efficiency and low power loss may be obtained at the same time.

In addition, with the manufacturing method of the solar cell module according to the present invention, the photoactive layer of the individual cell configuring the module may be manufactured integrally at one time by the coating or deposition method without separately performing patterning process, and the direction and the size of the entire voltage or the entire current of the module may be controlled only by the change in the disposition structure of the charge transport layer configuring the individual cells and the electrode, thereby providing cost reduction and various performances to the module.

### BRIEF DESCRIPTION OF THE DRAWINGS

FIG. 1 is a schematic view showing a solar cell module according to the related art;

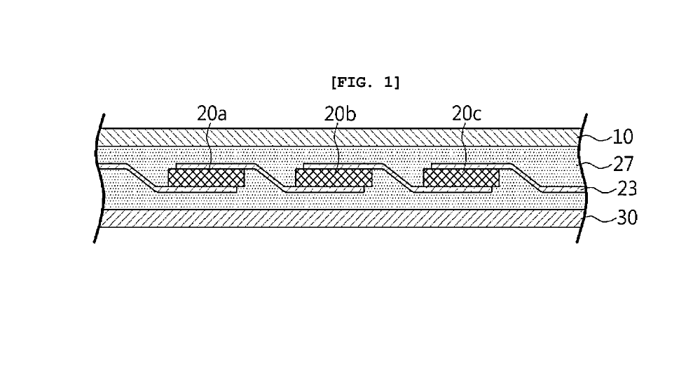

FIG. 2 is a perspective view showing a structure of a solar cell module according to an embodiment of the present invention;

FIG. 3a is a cross-sectional view showing a first cell configuring the solar cell module according to the embodiment of the present invention;

FIG. 3b is a cross-sectional view showing a second cell configuring the solar cell module according to the embodiment of the present invention;

FIG. 4a is a cross-sectional view showing a first sub-cell configuring the solar cell module according to the embodiment of the present invention;

FIG. 4b is a cross-sectional view showing a second sub-cell configuring the solar cell module according to the embodiment of the present invention;

FIG. 5 is a view showing a manufacturing method of the solar cell module according to the embodiment of the present invention;

FIG. 6a shows a J-V curve of a first sub-cell configuring the solar cell module according to the embodiment of the present invention; and

FIG. 6b shows a J-V curve of a second sub-cell configuring the solar cell module according to the embodiment of the present invention.

### MODE FOR INVENTION

Hereinafter, embodiments of the present invention will be described in detail with reference to the accompanying drawings. However, the present invention is not limited to embodiments to be described below but may be specified in other embodiments. Rather, the embodiments of the present invention are provided so that descriptions are thoroughly and completely explained and spirit of the present invention is sufficiently delivered to a person skilled in the art. In the drawings, thicknesses of layers and regions are exaggerated for clarity. Like reference numerals designate like components in the drawings of the present invention.

Since the present invention has various modifications and shapes, specific examples are exemplified in the drawings and described in detail. However, the present invention is not limited to the specifically described examples, but should be construed as including all the modifications, equivalents, and substitutions included in the spirit and scope of the present invention. Like components designate like reference numerals in describing each drawing.

Unless stated otherwise, all terms including technical or scientific terms have the same meanings as generally appreciated by a person skilled in the art. Terms generally defined in a dictionary should be construed as having the same meaning from the related technology, and unless explicitly defined in the present invention, the terms are not construed as ideally or excessively formal meaning.

Hereinafter, embodiments of the present invention will be described in detail with reference to the accompanying drawings.

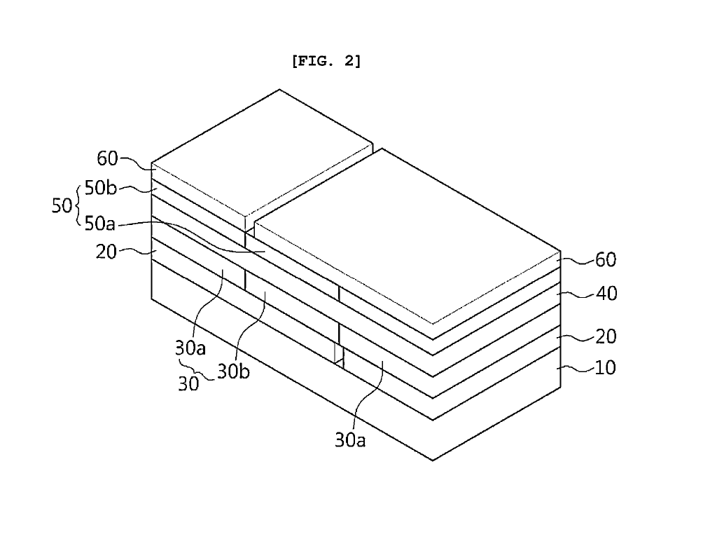

FIG. 2 is a perspective view showing a structure of a solar cell module according to an embodiment of the present invention.

Referring to FIG. 2, the solar cell module according to the embodiment of the present invention includes individual cells in which a first electrode 20, a first charge transport layer 30, a photoactive layer 40, a second charge transport layer 50, and a second electrode 60 are sequentially stacked on a substrate 10. Here, the first charge transport layer 30 or the second charge transport layer 50 may be omitted depending on a kind of material configuring the first electrode 20 or the second electrode 60.

The individual cells have a first cell shape or a second cell shape depending on dispositions of the charge transport layers 30 and 50, and are connected to neighboring cells through the first electrode 20 or the second electrode 60.

One set of the cells connected through the first electrode 20 is referred to as the first sub-cell, and one set of the cells connected through the second electrode 60 is referred to as the second sub-cell. That is, the sub-cell configuring the solar cell module may have two types as described above depending on a kind of electrode serving as a connecting part.

The first sub-cell and the second sub-cell include the first cell connected through the electrode 20 and the second cell connected through the electrode 60, respectively, the neighboring first sub-cell and the second sub-cell are connected to each other by sharing the first cells or the second cells to configure the solar cell module. Here, width of the first cell or the second cell configuring each sub-cell may be adjusted in order to match a current, as needed.

The substrate 10 may be a transparent inorganic substrate selected from a glass, quartz, Al₂O₃ and SiC or a transparent organic substrate selected from PET(polyethylene terephthlate), PES(polyethersulfone), PS(polystyrene), PC(polycarbonate), PI(polyimide), PEN(polyethylene naphthalate) and PAR(polyarylate).

The first electrode 20 formed on the substrate 10 may serve as a cathode or an anode depending on the kind of charge transport layer 30 disposed on the first electrode 20. For example, in the case in which a hole transport layer as the charge transport layer 30 is disposed on the first electrode 20, the first electrode 20 may serve as an anode collecting holes generated from the photoactive layer 40, and in the case in which an electron transport layer as the charge transport layer 30 is disposed on the first electrode 20, the first electrode 20 may serve as a cathode collecting electrons generated from the photoactive layer 40.

Since the first electrode 20 connects the neighboring cells, the first cell and the second cell may include a single first electrode 20.

It is preferred that the first electrode 20 is a material having transparency in order to transmit light. For example, the first electrode 20 may consist of carbon nanotube (CNT), carbon allotropes such as graphene, ITO, transparent conductive oxides (TCO) such as doped ZnO, MgO, and the like. In addition, conductive polymer materials such as polyacetylene, polyaniline, polythiophene, polypyrrole, and the like, may be used for the first electrode, and a metal grid wiring printed obtained by deposition or printed with an ink may be added for improving conductivity of the materials.

The first charge transport layer 30 formed on the first electrode 20 captures electrons or holes separated from the photoactive layer 40 and transports the captured electrons or holes to the first electrode 20.

The first charge transport layer 30 may be the first hole transport layer 30a or the first electron transport layer 30b. That is, the individual cells configuring the solar cell module may be provided by alternating the first charge transport layers 30 between the neighboring cells. For example, in the case in which the first cell is provided with the first hole transport layer 30a as the first charge transport layer 30, the neighboring second cell may be provided with the first electron transport layer 30b as the first charge transport layer 30.

The first hole transport layer 30a may be made of PSS(poly(3,4-ethylendioxythiophene):poly(styrenesulfonate)): PEDOT, polythiophenylenevinylene, polyvinylcarbazole, poly-p-phenylenevinylene, and derivatives thereof, but the present invention is not limited thereto, and various organic materials capable of increasing work function of the first electrode 20 contacting the first hole transport layer 30a may be used for the first hole transport layer. In addition, molybdenum oxide, vanadium oxide, tungsten oxide, and the like, which are p-typed doped metal oxide semiconductors, may be used.

The first electron transport layer 30b may be made of fullerene (C60, C70, C80) or fullerene derivatives PCBM([6,6]-phenyl-C61 butyric acid methyl ester)(PCBM(C60), PCBM(C70), PCBM(C80)), but the present invention is not limited thereto, and various organic materials capable of decreasing work function of the first electrode 20 contacting the first hole transport layer 30a may be used for the first electron transport layer (such as polyethylene imine (PEI), PEI derivatives, and Polyethylene oxide(PEO)). In addition, titanium oxide (TiOₓ), zinc oxide (ZnO) and the like, which are n-typed doped metal oxide semiconductors, may be used.

The photoactive layer 40 formed on the first charge transport layer 30 absorbs light irradiated on the solar cell to form an electron-hole pair in an excitation state, that is, an exciton.

The photoactive layer 40 is formed integrally so as to penetrate through the individual cells. That is, the individual cells include an integrally connected one photoactive layer. Therefore, a material and an electrode penetrating through the photoactive layer interconnecting the individual cells are not separately required.

The photoactive layer 40 has a bulk hetero junction structure or a bilayer structure of electron donor materials and electron acceptor materials.

The electron donor material may include an organic material absorbing light. For example, the electron donor material may be a conjugated polymer including [poly-3-hexylthiophene, P3HT], [poly-3-octylthiophene, P3OT], [poly-p-phenylenevinylene, PPV], [poly(9,9′-dioctylfluorene)], [poly(2-methoxy, 5-(2-ethyle-hexyloxy)-1,4-phenylenevinylene, MEH-PPV], [poly(2-methyl, 5-(3′,7′-dimethyloctyloxy))-1,4-phenylene vinylene, MDMO-PPV], and the like, and modifications thereof or organic monomers including CuPc, ZnPc, and the like.

In addition, the electron acceptor material may be an organic material including fullerene (C60, C70, and C80) or fullerene derivatives PCBM([6,6]-phenyl-C61 butyric acid methyl ester)(PCBM(C60), PCBM(C70), PCBM(C80)), ICBA(indene-C60 bisadduct)(ICBA(c60), (ICBA(c70), (IC80BA(c80)), carbon nanotube or graphene or an inorganic material including a metal oxide such as ZnO, TiO₂, SnO₂, or the like. However, the electron acceptor material is not limited thereto, but may be various materials capable of receiving electrons from the photoactivated electron acceptor material.

The second charge transport layer 50 formed on the photoactive layer 40 captures electrons or holes separated from the photoactive layer 40 and transports the captured electrons or holes to the second electrode 60.

The second charge transport layer 50 may be the second hole transport layer 50a or the second electron transport layer 50b. That is, the individual cells configuring the solar cell module may be provided by alternating the second charge transport layers 50 between the neighboring cells. For example, in the case in which the first cell is provided with the second hole transport layer 50a as the second charge transport layer 50, the neighboring second cell may be provided with the second electron transport layer 50b as the second charge transport layer 50.

In addition, the individual cells have a disposition structure in which they are opposite to each other in a relationship with the first charge transport layer 30. That is, the first hole transport layer 30a and the second electron transport layer 50b face each other, and the first electron transport layer 30b and the second hole transport layer 50a face each other, having the photo active layer 40 therebetween. Here, the second hole transport layer 50a may be made of the same material as the first hole transport layer 30a and the second electron transport layer 50b may be made of the same material as the first electron transport layer 30b.

The second electrode 60 formed on the second charge transport layer 50 may serve as a cathode or an anode depending on a kind of second charge transport layer 50. For example, in the case in which the second charge transport layer 50 is the hole transport layer, the first electrode 60 may serve as an anode collecting holes generated from the photoactive layer 40, and in the case in which the second charge transport layer 50 is the electron transport layer, the second electrode 60 may serve as a cathode collecting electrons generated from the photoactive layer 40.

Since the second electrode 60 connects neighboring cells, the first cell and the second cell may include a single second electrode 20.

The second electrode 60 may be any one of metal electrodes selected from Al, Au, Cu, Pt, Ag, W, Ni, Zn or Ti, and alloys thereof. In addition, conductive polymer materials such as polyacetylene, polyaniline, polythiophene, polypyrrole, ITO, transparent conductive oxides (TCO) such as, doped ZnO, MgO, transparent metal mesh such as Ag mesh, and the like, may be used for the second electrode 60.

The first electrode 20 and the second electrode 60 may be used by changing positions thereof conversely. For example, a solar cell manufactured by disposing a metal electrode as the first electrode 20, and a conductive film having transparency as the second electrode 60, may receive light at an upper portion thereof.

In the solar cell module according to the present invention, the conductive polymer may be used in both of the first electrode and the second electrode. The reason is that the holes transported through the hole transport layer are easily moved to an interface of the electron transport layer along the first electrode or the second electrode connecting the neighboring cells and a serial connection condition of a solar cell to be coupled with the electron is satisfied.

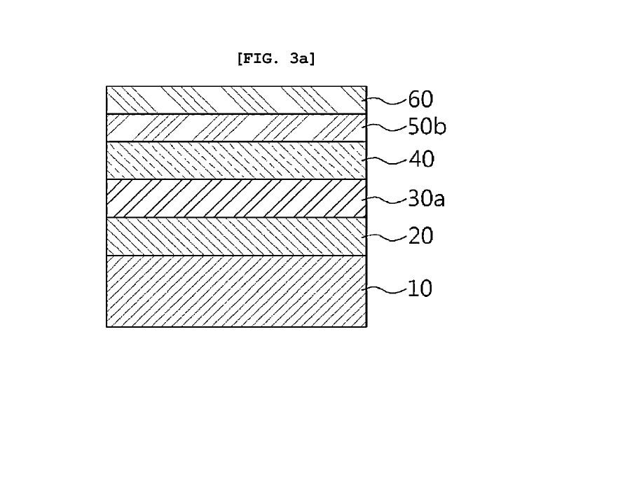

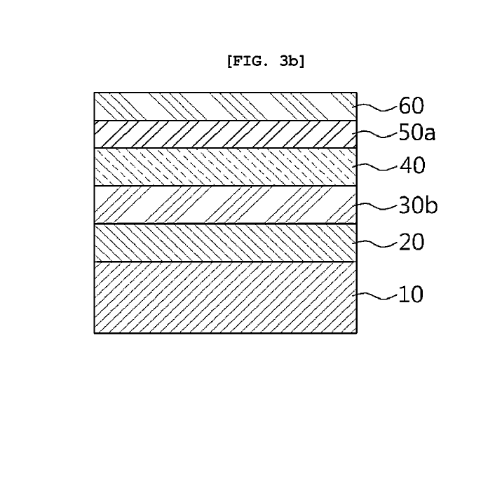

FIG. 3a is a cross-sectional view showing the first cell configuring the solar cell module according to the embodiment of the present invention.

FIG. 3b is a cross-sectional view showing the second cell configuring the solar cell module according to the embodiment of the present invention.

Referring to FIGS. 3a and 3b, the first cell configuring the solar cell module according to the embodiment of the present invention includes the substrate 10, the first electrode, the first hole transport layer 30a, the photoactive layer 40, the second electron transport layer 50b, and the second electrode 60. Therefore, in the case of the first cell, the first hole transport layer 30a is formed on the first electrode, such that the first electrode 20 may serve as an anode collecting holes generated from the photoactive layer 40, and the second electron transport layer 50b is formed in a lower portion of the second electrode 60, such that the second electrode 60 may serve as a cathode collecting electrons generated from the photoactive layer 40.

In addition, the second cell includes the substrate 10, the first electrode, the first electron transport layer 30b, the photoactive layer 40, the second hole transport layer 50a, and the second electrode 60. Therefore, in the case of the second cell, the first electron transport layer 30b is formed on the first electrode, such that the first electrode 20 may serve as a cathode collecting electrons generated from the photoactive layer 40, and the second hole transport layer 50a is formed in a lower portion of the second electrode 60, such that the second electrode 60 may serve as an anode collecting holes generated from the photoactive layer 40.

In the solar cell module according to the present invention, the first cell and the second cell are repeated while neighboring with each other. A direction of the photocurrent or a pole of an open voltage may be changed depending on dispositions of the first cell and the second cell. Here, width of the first cell or the second cell may be adjusted in order to match a current, as needed.

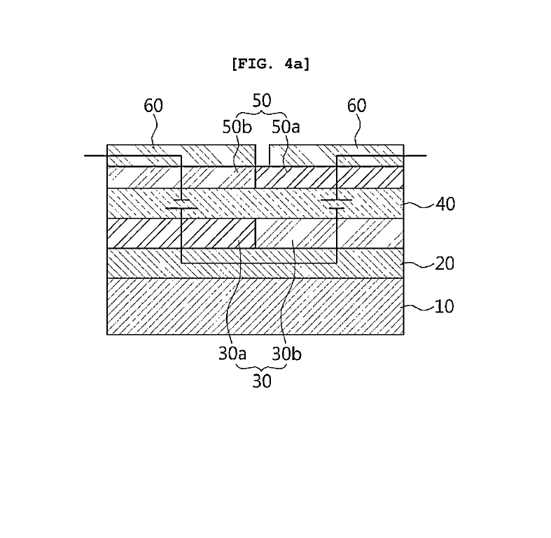

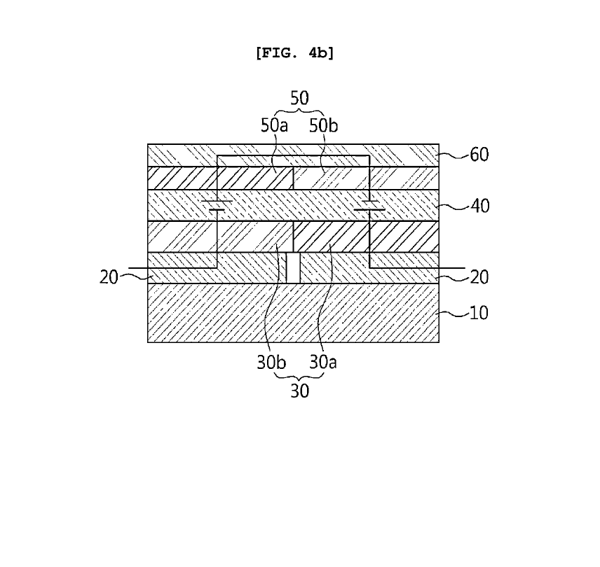

FIG. 4a is a cross-sectional view showing the first sub-cell configuring the solar cell module according to the embodiment of the present invention.

FIG. 4b is a cross-sectional view showing the second sub-cell configuring the solar cell module according to the embodiment of the present invention.

Referring to FIGS. 4a and 4b, the individual cells configuring the solar cell module have a first cell shape or a second cell shape depending on dispositions of the charge transport layers 30 and 50, and are connected to the neighboring cells through the first electrode 20 or the second electrode 60. One set of the cells connected through the first electrode 20 is referred to as the first sub-cell, and one set of the cells connected through the second electrode 60 is referred to as the second sub-cell. That is, the sub-cell configuring the solar cell module may have two types of the first sub-cell including the single first electrode 20 and the second sub-cell including the single second electrode 60.

The first sub-cell includes the first electrode 20 on the substrate 10, the first charge transport layer 30 in which the first hole transport layer 30a and the first electron transport layer 30b are disposed in a neighboring way, the photoactive layer 40, the second charge transport layer 50 in which the second electron transport layer 50b and the second hole transport layer 50a are disposed in a neighboring way, and the second electrode 60. That is, the first sub-cell may have a structure in which the first cell and the second cell are sequentially stacked, and the first cell and the second cell may share the first electrode and the second electrode may share the neighboring other cell.

The second sub-cell includes the first electrode 20 on the substrate 10, the first charge transport layer 30 in which the first electron transport layer 30b and the first hole transport layer 30a are disposed in a neighboring way, the photoactive layer 40, the second charge transport layer 50 in which the second hole transport layer 50a and the second electron transport layer 50b are disposed in a neighboring way, and the second electrode 60. That is, the second sub-cell may have a structure in which the second cell and the first cell are sequentially stacked, and the first cell and the second cell may share the second electrode and the first electrode may share the neighboring other cell.

As described above, the first sub-cell and the second sub-cell includes the first cell and the second cell connected through the first electrode 20 or the second electrode 60, respectively, and the electrodes 20 and 60 serve as a connecting part connecting the individual cells. Therefore, the holes transported through the hole transport layer are easily moved to an interface of the electron transport layer along the electrodes 20 and 60 and a serial connection condition to be coupled with the electron is satisfied, thereby providing an advantage that the conductive polymer may be used in both of the anode and the cathode.

The first sub-cell and the second sub-cell are repeatedly disposed, and the neighboring first sub-cell and the second sub-cell are connected to each other by sharing the first cells or the second cells to configure the solar cell module. Therefore, a direction of the photocurrent or a pole of an open voltage may be changed depending on dispositions of the first sub-cell and the second sub-cell. In addition, width of the first cell or the second cell configuring each sub-cell may be adjusted in order to match a current, as needed.

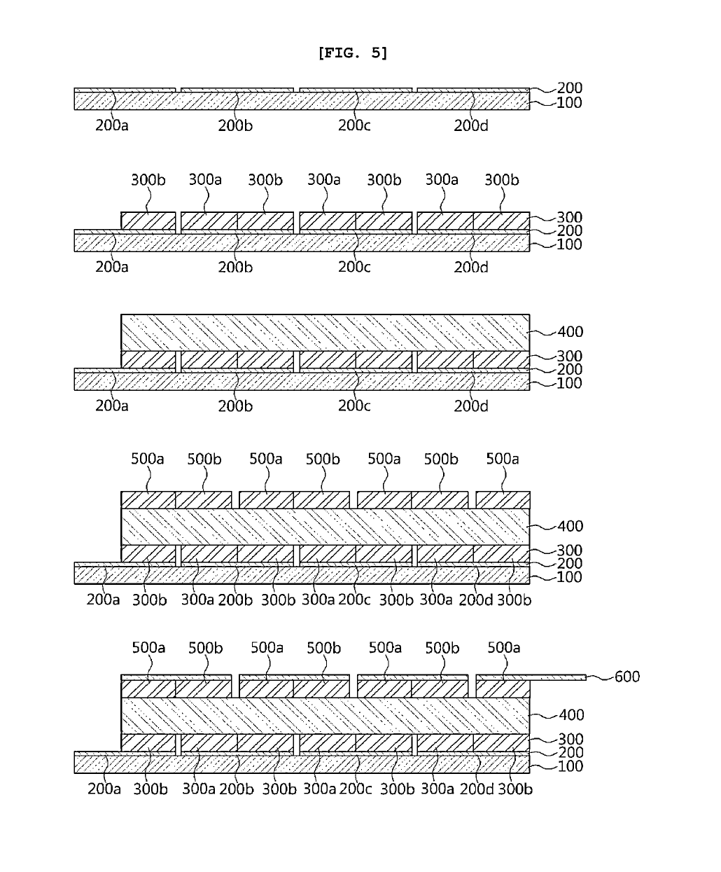

FIG. 5 is a view showing a manufacturing method of a solar cell module according to an embodiment of the present invention.

Referring to FIG. 5, a first electrode part 200 is formed on a substrate 100. The substrate may be a transparent inorganic substrate or a transparent organic substrate. The first electrode part 200 may consist of a plurality of first electrodes 200a, 200b, 200c and 200d configuring each cell, wherein the plurality of first electrodes 200a, 200b, 200c and 200d are formed by manufacturing and scribing one electrode. The present invention shows four electrodes, but is not limited thereto, and the number of electrodes and a length thereof may be changed so as to be appropriate for each need. The first electrode part 200 including the plurality of first electrodes 200a, 200b, 200c and 200d disposed so as to be in parallel with each other and spaced apart at a predetermined distance is formed.

It is preferred that the first electrode part 200 formed on the substrate 100 is made of a material having transparency in order to transmit light. Therefore, the first electrode part 200 may be made of carbon allotropes and transparent conductive oxide (TCO). In addition, the first electrode part 200 may be made of a conductive polymer material.

Then, a first charge transport part 300 is formed on the first electrode part 200. The first charge transport part 300 includes a first hole transport layer 300a and a first electron transport layer 300b, and two kinds of charge transport layers are alternated with each other. Therefore, the first hole transport layer 300a and the first electron transport layer 300b are disposed so as to neighbor each other. That is, the first charge transport part 300 may be formed by repeating a first hole transport layer 300a—a first electron transport layer 300b—a first hole transport layer 300a—a first electron transport layer 300b—, and the like, in a sequence, or by repeating a first electron transport layer 300b—a first hole transport layer 300a—a first electron transport layer 300b—a first hole transport layer 300a—, and the like, in a sequence.

Here, one set of the first hole transport layer 300a/the first electron transport layer 300b is formed so as to contact one first electrode, which consists of the first sub-cell. Since one set of the first hole transport layer 300a and the first electron transport layer 300b formed on one electrode is positioned in the same dislocation as described above, a side surface contact of two charge transport layers is possible, thereby making it possible to minimize a power loss area.

The first charge transport part 300 may be formed by performing a solution process appropriately selected from slot-die printing, spray printing, electrospray printing, screen printing, ink-jet printing, gravure printing, or offset printing, as needed, or by performing a deposition process using a mask.

The photoactive layer 400 is formed on the first charge transport part 300. Here, the photoactive layer 400 is formed integrally so as to penetrate through the individual cells. Therefore, the photoactive layer 400 included in the individual cells may be formed integrally. Therefore, since a patterning process is not separately required, the manufacturing process is capable of being simplified.

The photoactive layer 400 has a bulk hetero junction structure or a bilayer structure of electron donor materials and electron acceptor materials.

The photoactive layer 400 may be formed by performing a coating or printing process appropriately selected from slot-die printing, screen printing, ink-jet printing, gravure printing, offset printing, doctor blade coating, knife edge coating, dip coating and spray coating, as needed, or by performing a deposition process.

The second charge transport part 500 is formed on the photoactive layer 400. The second charge transport part 500 includes a second electron transport layer 500b and a second hole transport layer 500a, and two kinds of charge transport layers are alternated with each other. Therefore, the second electron transport layer 500b and the second hole transport layer 500a are disposed so as to neighbor each other. Here, the disposition structure of the second charge transport part is opposite to the disposition structure of the first charge transport part 300. That is, the first hole transport layer 300a and the second electron transport layer 500b face each other, and the first electron transport layer 300b and the second hole transport layer 500a face each other, having the photoactive layer 400 therebetween.

The second charge transport part 500 may be formed by performing a solution process appropriately selected from slot-die printing, spray printing, electrospray printing, screen printing, ink-jet printing, gravure printing, or offset printing, as needed, or by performing a deposition process using a mask.

Then, a second electrode part 600 is formed on the second charge transport part 500. The second electrode part 500 may consist of a plurality of second electrodes 600a, 600b, 600c and 600d, wherein the plurality of second electrodes 600a, 600b, 600c and 600d may be formed by manufacturing and scribing one electrode. Therefore, the second electrode part 600 including the plurality of second electrodes 600a, 600b, 600c and 600d disposed so as to be in parallel with each other and spaced apart at a predetermined distance is formed.

Here, one set of the second hole transport layer 500a/the second electron transport layer 500b is formed so as to contact one second electrode, which consists of the second sub-cell. Since one set of the second hole transport layer 500a and the second electron transport layer 500b formed on one electrode is positioned in the same dislocation as described above, a side surface contact of two charge transport layers is possible, thereby making it possible to minimize a power loss area.

In addition, the second electrode part 600 and the first electrode part 200 are formed so as to face each other, having a predetermined interval therebetween, wherein the interval corresponds to width of a layer configuring the first charge transport part 300 or the second charge transport part 500. That is, the first electrode 200a and the second electrode 600a share one cell configuring the sub-cell. Therefore, the first electrode part 200 and the second electrode part 600 serve to connect each cell configuring the module in series, thereby having a problem in that a wiring area for connection of each cell is not separately required.

The second electrode part 600 may include a metal, an alloy or a conductive polymer material, or may be formed by thermal deposition. In addition, in the case in which the second electrode part 600 is made of the metal electrode, the metal may be fabricated in an ink type and formed by a solution process such as screen printing, ink jet printing, gravure printing, offset printing, or the like. The solution process may be performed in a large area and may decrease a manufacturing process cost.

As described above, with the manufacturing method of the solar cell module according to the present invention, the individual cells configuring the module may be manufactured at one time.

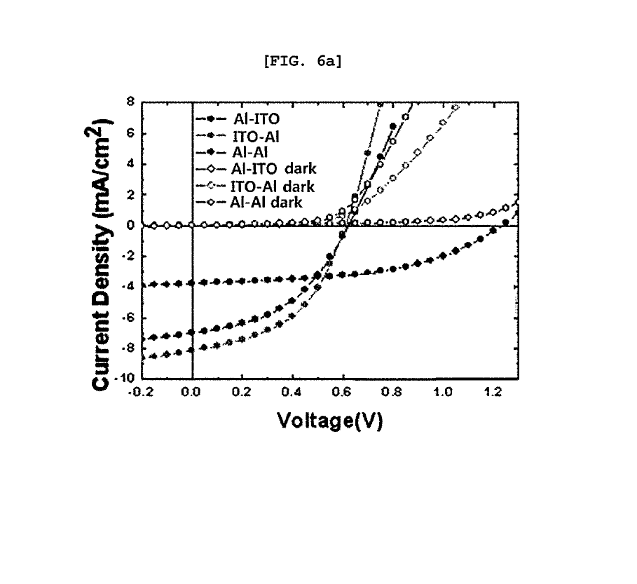

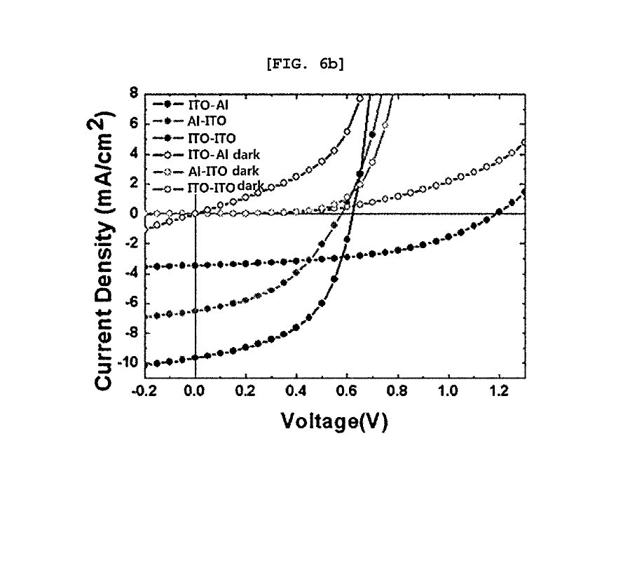

FIG. 6a shows a J-V curve of the first sub-cell configuring the solar cell module according to the embodiment of the present invention.

FIG. 6b shows a J-V curve of the second sub-cell configuring the solar cell module according to the embodiment of the present invention.

In order to measure the J-V curve, all solar cell module samples were manufactured and the sample was thermal deposited on the glass substrate to form an ITO transparent electrode, and a PEDOT:PSS thin film layer as a hole transport layer and a TiOₓ thin film layer as an electron transport layer are alternately disposed on the ITO transparent electrode, thereby forming a first charge transport part. The first charge transport part was formed by a tape casting using a doctor blade. A P3HT:PCBM thin film layer as a photoactive layer was formed on the first charge transport part using spin coating, and a PEDOT:PSS thin film layer as a hole transport layer was formed on the photoactive layer. Here, the PEDOT:PSS thin film layer was formed by a tape casting using a doctor blade. Then, an Al electrode was formed by thermal deposition. In the case of the Al electrode, since work function thereof is decreased, the Al electrode may be used as a cathode, such that in the case of the second charge transport part, TiOₓ thin film layer which is an electron transport layer was not separately disposed.

Therefore, the module manufactured by the above-described process may include the first cell consisting of a glass substrate-ITO transparent electrode-PEDOT:PSS layer-P3HT:PCBM layer-Al electrode, and the second cell consisting of a glass substrate-ITO transparent electrode-TiOₓ layer-P3HT:PCBM layer-PEDOT:PSS layer-Al electrode, and may include the first sub-cell and the second sub-cell consisting of the first cell/the second cell/or the second cell/the first cell, depending on disposition sequence of the first cell and the second cell.

Referring to FIGS. 6a and 6b, voltage and current density in Al electrode-ITO electrode section, ITO electrode-Al electrode section, Al electrode-Al electrode section were measured from the first sub-cell and voltage and current density in ITO electrode-Al electrode section, Al electrode-ITO electrode section, ITO electrode-ITO electrode section were measured from the second sub-cell. Here, for comparison, a state in which each sub-cell is not operated was shown as dark which is not highlighted. After measurement, it could be appreciated that an open circuit voltage (Voc) in Al electrode-ITO electrode section, ITO electrode-Al electrode section, ITO electrode-Al electrode section, Al electrode-ITO electrode section was about 0.6V, which is two times larger than an open circuit voltage in Al electrode-Al electrode section, ITO electrode-ITO electrode section which was about 1.2V. Therefore, it could be appreciated that in the solar cell module according to the embodiment of the present invention, each cell configuring the module was connected to the neighboring cell in series through the electrode.

With the solar cell module according to the present invention, the individual cells configuring the module are connected in series to each other through the electrode, such that a current may be decreased and a voltage may be increased, and additional space for connecting the individual cells in series to each other is not required, such that high photovoltaic conversion efficiency and low power loss may be obtained at the same time.

1. A solar cell module comprising:
a plurality of first solar cells including a first electrode, a photoactive layer, and a second electrode; and
a plurality of second solar cells including a first electrode, a photoactive layer, and a second electrode,
wherein the first solar cell and the second solar cell include at least one charge transport layer selected from a hole transport layer and an electron transport layer, the charge transport layers between the first solar cell and the second solar cell that are alternated with each other so as to neighbor and be adjacent to each other being disposed so as to be alternated with each other;
the first solar cell and the second solar cell are connected to neighboring cells through the first electrode or the second electrode, and
photoactive layers of the first solar cell and the second solar cell are formed integrally so as to penetrate through each cell.

2. The solar cell module of claim 1, wherein the first solar cell and the second solar cell include a substrate; the first electrode formed on the substrate; a first charge transport layer formed on the first electrode; the photoactive layer formed on the hole transport layer; the second charge transport layer formed on the photoactive layer; and the second electrode formed on the second charge transport layer.

3. The solar cell module of claim 1, wherein any one of the first electrode and the second electrode of the neighboring first solar cell and second solar cell is formed integrally to thereby interconnect the cells.

4. The solar cell module of claim 2, wherein any one of the first charge transport layers of the neighboring first solar cell and the second solar cell is a hole transport layer and the other is an electron transport layer.

5. The solar cell module of claim 2, wherein any one of the second charge transport layers of the neighboring first solar cell and the second solar cell is a hole transport layer and the other is an electron transport layer.

6. The solar cell module of claim 2, wherein the first electrode is operated as an anode or a cathode depending on a kind of the first charge transport layer.

7. The solar cell module of claim 1, wherein the photoactive layer has a bulk hetero junction structure of an electron donor material and an electron acceptor material.

8. The solar cell module of claim 7, wherein the electron donor material contains a conjugated polymer or an organic monomer.

9. The solar cell module of claim 7, wherein the electron acceptor material contains a carbon allotrope or a metal oxide.

10. The solar cell module of claim 2, wherein the second electrode is operated as an anode or a cathode depending on a kind of the second charge transport layer.

11. The solar cell module of claim 1, wherein the first electrode or the second electrode contains a conductive polymer.

12. A manufacturing method of a solar cell module, the manufacturing method comprising:
forming a first electrode part on a substrate, the first electrode part including a plurality of first electrodes spaced apart from each other;
forming a first charge transport part by disposing first hole transport layer and first electron transport layer on the first electrode part so as to be alternated with each other;
forming a photoactive layer integrally on the first charge transport part;
forming a second charge transport part by disposing second electron transport layer and second hole transport layer on the photoactive layer so as to be alternated with each other; and
forming a second electrode part on the second charge transport part, the second electrode part including a plurality of second electrodes spaced apart from each other.

13. The manufacturing method of claim 12, wherein the photoactive layer is formed by any one method selected from slot-die printing, screen printing, ink-jet printing, gravure printing, offset printing, doctor blade coating, knife edge coating, dip coating and spray coating, or by deposition.

14. The manufacturing method of claim 12, wherein the first hole transport layer and the first electron transport layer are formed on each first electrode so as to contact each other.

15. The manufacturing method of claim 12, wherein the second hole transport layer and the second electron transport layer are formed in a lower portion of each second electrode so as to contact each other.

16. The manufacturing method of claim 12, wherein the first charge transport part and the second charge transport part are formed so that the transport layers having different charges face each other, having the photoactive layer therebetween.

17. The manufacturing method of claim 12, wherein the first electrode part or the second electrode part is formed by any one selected from slot-die printing, screen printing, ink-jet printing, gravure printing, offset printing, thermal deposition, and sputtering.

18. The manufacturing method of claim 13, wherein the first charge transport part and the second charge transport part are formed by any one method selected from slot-die printing, screen printing, ink-jet printing, gravure printing, and offset printing, or by deposition using a mask.
